(19) United States
(12) Patent Application Publication
(10) Pub. No.: US 2008/0068027 A1
(43) Pub. Date: Mar. 20, 2008

(54) Power line surge arrestor monitoring system

(75) Inventors: Charles Crain, Colorado Springs, CO (US); Philip Lane, Colorado Springs, CO (US); Kelly Rice, Colorado Springs, CO (US); James Youngman, Woodland Park, CO (US)

Correspondence Address: FITCH EVEN TABIN AND FLANNERY, 120 SOUTH LA SALLE STREET, SUITE 1600, CHICAGO, IL, 60603-3406, US

(73) Assignee: L-3 Communications Corporation

(21) Appl. No.: 11/523,939

(22) Filed: Sep. 20, 2006

(51) Int. Cl. G01R 31/08

(52) U.S. Cl. 324/522

(57) ABSTRACT

A monitoring system in accordance with one embodiment comprising a plurality of surge arrestors; a plurality of probes coupled, each one of the plurality of probes coupled to one of the plurality of surge arrestors; the plurality of probes comprising at least one current probe and at least one voltage probe; a switching matrix coupled to the plurality of probes; and an electronic measuring device coupled to the switch, the electronic measuring device for measuring signals from the plurality of probes, the signals corresponding to a status of each of the plurality the surge arrestors.

### FIELD OF THE INVENTION

The present invention relates to surge arrestors. More specifically, the present invention relates to monitoring of surge arrestors.

### BACKGROUND OF THE INVENTION

Generally, surge arrestors provide power line and signal line protection for many different types of facilities including, for example, commercial facilities, banks, office buildings, military facilities, missile silos, hangers, commercial power stations, telecommunication switching systems, and many other types of facilities. Any facility that has one or more surge arrestors that protect the facility from power surges coming from the power grid generally has a person that checks the status of the surge arrestors. Generally, this requires the person physically going to each surge arrestor and manually checking the surge arrestor or checking an indicator light which signals to the person whether an indicator fuse has been blown. If the fuse has been blow, an assumption is made by the person checking the system that the surge arrestor is also bad.

There are a number of problems with the above monitoring system. First, many of the facilities where the surge arrestors are located are very remote and do not have maintenance staff that are regularly at the facility. Thus, the surge arrestors can not be readily inspected. Second, as can be seen in FIG. 1, the surge arrestors can be contained within a large, heavy duty, cabinet. The surge arrestor can only be inspected by removing a panel on the cabinet. As shown in FIG. 1, a plurality of bolts hold the panel to the cabinet for safety. The task of removing all of the bolts in order to inspect the surge arrestor can be fairly labor intensive. Therefore, there is a large cost required to maintain an employee who must perform the task of monitoring the surge arrestors for a facility. Thus, what is needed is a way to monitor a surge arrestor without the need to be at the location of the surge arrestor or without the need to remove the panel on the cabinet where the surge arrestor is located.

### SUMMARY OF THE INVENTION

The embodiments described herein provide systems and methods for monitoring one or more surge arrestors.

One embodiment can be characterized as a system for monitoring a surge arrestor comprising a current probe for measuring a total current (reactive and/or resistive) through the surge arrestor; and an electronic measuring device connected to the current probe, the electronic measuring device for measuring a signal from the current probe, the signal corresponding to the total current of the surge arrestor, a fuse coupled to the surge arrestor and a voltage probe coupled to the fuse and the surge arrestor.

Another embodiment can be characterized as a method for monitoring a surge arrestor comprising coupling a first current probe and a voltage probe to a first surge arrestor; measuring an output of the first current probe and voltage probe at an electronic measuring device; and determining a status of the first surge arrestor based upon the measured output of the current probe and the voltage probe.

A subsequent embodiment includes a monitoring system comprising a surge arrestor; a fuse coupled to the surge arrestor; a probe coupled between the fuse and the surge arrestor; and an electronic measuring device coupled to the probe, the electronic measuring device for measuring a signal from the probe, the signal corresponding to a status of the surge arrestor.

Yet another embodiment can be characterized as a monitoring system comprising a plurality of surge arrestors; a plurality of probes coupled, each one of the plurality of probes coupled to one of the plurality of surge arrestors; wherein at least one of the plurality of probes is a current probe and at least one is a voltage probe; a switching matrix coupled to the plurality of probes; and an electronic measuring device coupled to the switch, the electronic measuring device for measuring signals from the plurality of probes, the signals corresponding to a status of each of the plurality the surge arrestors.

### BRIEF DESCRIPTION OF THE DRAWINGS

The above and other aspects, features and advantages of the present invention will be more apparent from the following more particular description thereof, presented in conjunction with the following drawings, wherein:

FIG. 1 is a diagram of a cabinet for housing one or more surge arrestors in accordance with one embodiment;

FIG. 2 is a block diagram illustrating a monitoring system for monitoring a surge arrestor in accordance with one embodiment;

FIG. 3 is a block diagram illustrating a monitoring system for monitoring a plurality of surge arrestors in accordance with one embodiment;

FIG. 4 is a graphical representation of a total current of a surge arrestor as measured by an oscilloscope in accordance with one embodiment; and

FIG. 5 is a graphical representation of a total current of a surge arrestor as measured by a spectrum analyzer in accordance with one embodiment.

Corresponding reference characters indicate corresponding components throughout the several views of the drawings. Skilled artisans will appreciate that elements in the figures are illustrated for simplicity and clarity and have not necessarily been drawn to scale. For example, the dimensions, sizing, and/or relative placement of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention. It will also be understood that the terms and expressions used herein have the ordinary meaning as is usually accorded to such terms and expressions by those skilled in the corresponding respective areas of inquiry and study except where other specific meanings have otherwise been set forth herein.

### DETAILED DESCRIPTION

The following description is not to be taken in a limiting sense, but is made merely for the purpose of describing the general principles of the invention. The scope of the invention should be determined with reference to the claims. The present embodiments address the problems described in the background while also addressing other additional problems as will be seen from the following detailed description.

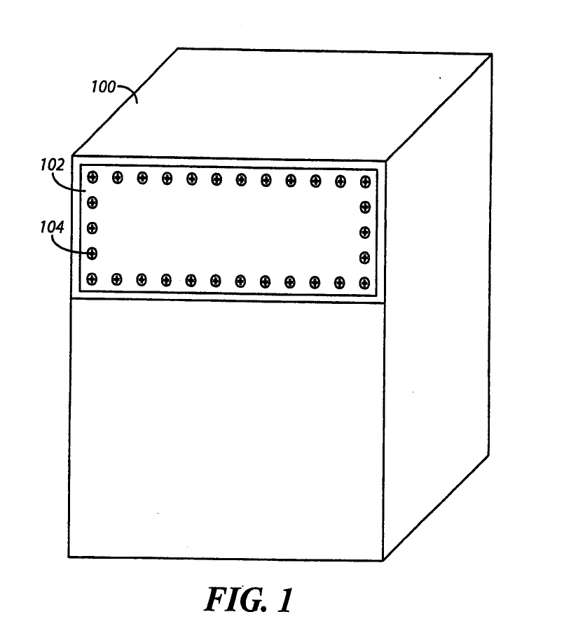

Referring to FIG. 1 a diagram is shown of a cabinet 100 for housing one or more surge arrestors in accordance with one embodiment. As described above, the cabinet 100 includes a panel 102 and a plurality of bolts 104.

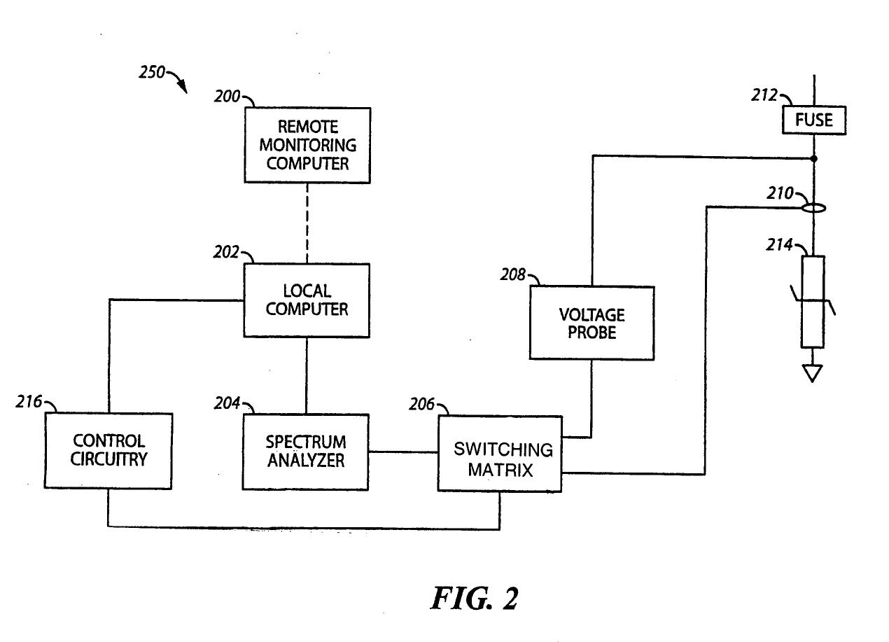

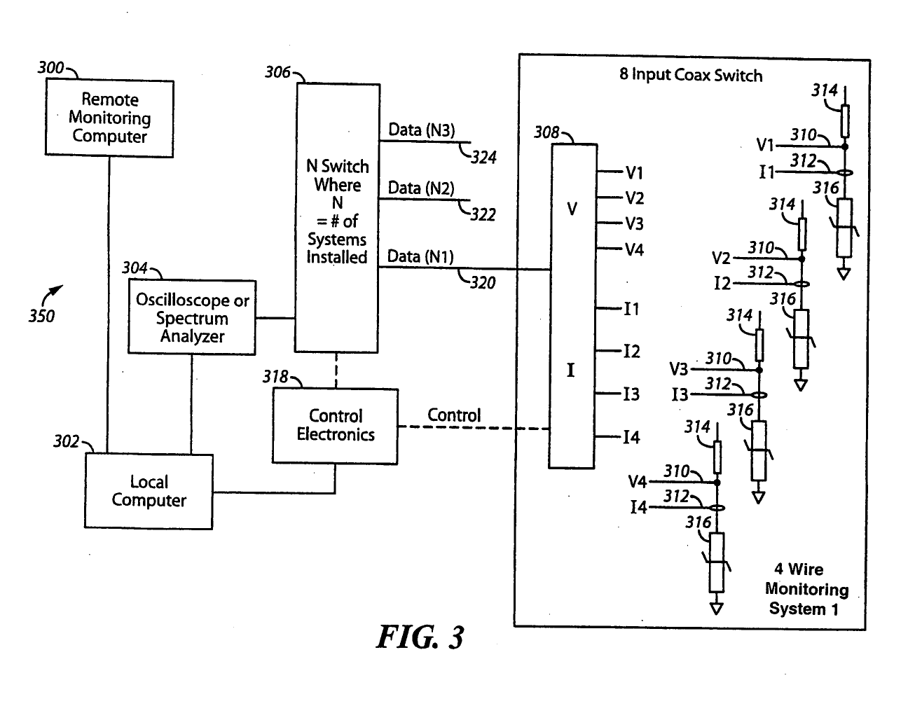

One or more surge arrestors are located within the cabinet 100. A facility may include one or more cabinets and thus, one or more surge arrestors. The embodiments described below with reference to FIGS. 2 and 3 provide systems and methods for monitoring the status of the surge arrestors without the need to remove the panel 102 from the cabinet 100. Furthermore, some embodiments allow for the status of the surge arrestors to be monitored at a computer located at the facility or by a remotely located computer that is connected to the facility, for example, via an intranet or the Internet. Advantageously, these embodiments remove the need for a person to visually inspect the surge arrestors by removing the panel 102 from the cabinet 100.

Referring to FIG. 2, a block diagram is shown illustrating a monitoring system 250 for monitoring a surge arrestor in accordance with one embodiment. Shown is a remote computer 200, a local computer 202, an electronic measuring device 204, a switching matrix 206, a voltage probe 208, a current probe 210, a fuse 212, a surge arrestor 214, and control circuitry 216.

The remote computer 200 is coupled to the local computer through any type of network (e.g., the Internet, an Ethernet connection, a local area network, a wireless network, a virtual private network or other type of connection that allows communication between the remote computer 200 and the local computer 202). The local computer 202 is coupled to the electronic measuring device 204 such that data can be transferred from the electronic measuring device to the local computer 202. The electronic measuring device 204 is, for example, a spectrum analyzer, oscilloscope or other device that is capable of measuring voltage and/or current in either the frequency or time domain. The electronic measuring device 204 can also be a part of local computer 202 (e.g., a plug in card). The electronic measuring device 204 is coupled to the computer through, for example, a Universal Serial Bus (USB) connection, an Ethernet connection, an interface in accordance with IEEE 1394 standards, a general purpose interface bus (GPIB) or other known means of communicating data from a spectrum analyzer or oscilloscope to a computer.

The voltage probe 208 and the current probe 210 are coupled to the electronic measuring device 204 through the switching matrix 206. As defined herein, a switching matrix includes one or more physical or logical switches. The switching matrix is controlled by the control circuitry 216. The control circuitry 216 is any combination of hardware, software, and/or firmware and can be implemented as a dedicated fixed-purpose circuit and/or partially or wholly programmable platform. The control circuitry 216 can be implemented as a separate device or can be implemented as a module within either of the local computer 202 or the remote computer 204.

The voltage probe 208 is also coupled between the fuse 212 and the surge arrestor 214. The current probe 210 is coupled to a lead of the surge arrestor 214. Advantageously, in accordance with one embodiment, the current probe 210 is an inductive current probe that is placed around an input wire to the surge arrestor 214. In this manner, the current probe 210 is not physically connected to the surge arrestor 214.

The surge arrestor 214 is, for example, a metal oxide varistor (MOV), a spark gap type arrestor, a diode or Zener technology. Each of these devices has an inherent capacitance and thus, has at least a small total current present at the surge arrestor 214. The current probe 210 is coupled to the surge arrestor 214 and measures the total current in the surge arrestor 214. In general, the capacitance of the surge arrestor 214 is directly related to the health of the surge arrestor 214. Additionally, the capacitance 214 is also related to the total current in the surge arrestor 214. Thus, by measuring the total current with the current probe 210, a determination as to the status or health of the surge arrest 214 can be made. Furthermore, as MOVs age or experience normal system voltage surges, parts of their semi-conductor matrix heat and fuses together. This lowers the breakdown or function voltage of the MOV and increases the total current. Eventually, the breakdown voltage of the MOV lowers significantly to cause a catastrophic avalanche and failure of the MOV. The current probe 210 can be used to monitor the total current and the measured signal can be analyzed to determine a status, failure of the surge arrestor and/or changes in device characteristics with age.

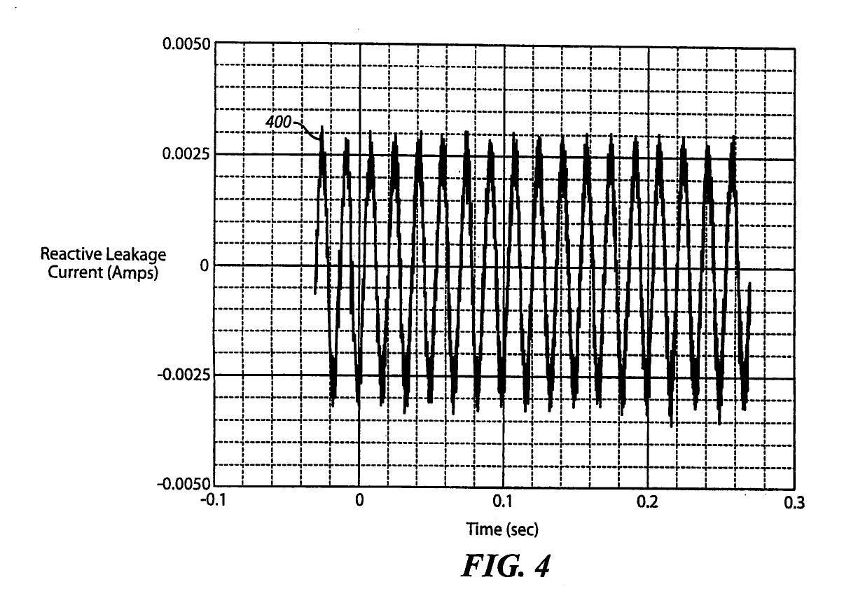

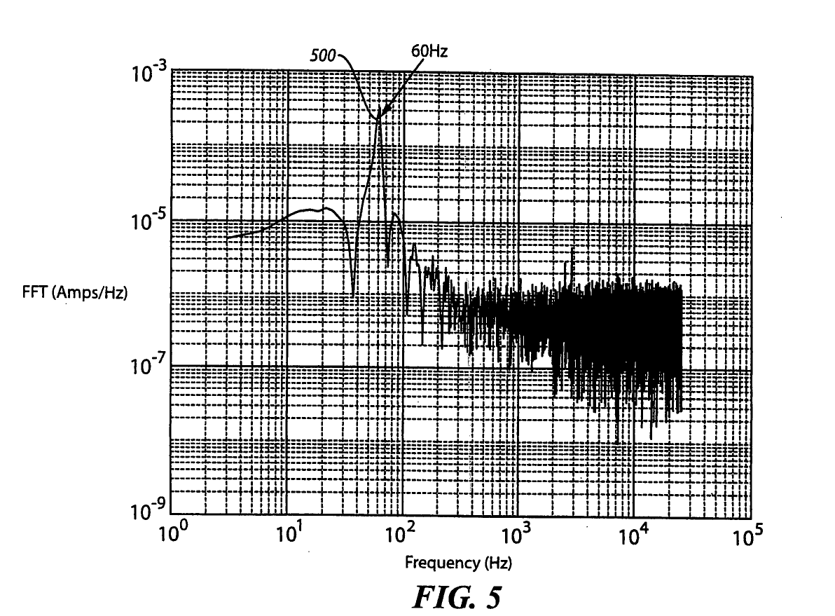

In operation, the current probe 210 measures a total current from the surge arrestor 214. The total current is present due to the charging and discharging of the inherent capacitance of the surge arrestor 214. In accordance with one embodiment, the current probe 210 is an inductive current probe, for example, a 1 V/A current probe (with a sensitivity of 1 V/A at 60 Hz.) The output signal of the current probe 210 is input to the electronic measuring device 204 through the switching matrix 206. The electronic measuring device 204 measures the output signal from the current probe and stores data corresponding to the output signal. As described above, the electronic measuring device 204 is, for example, a spectrum analyzer or an oscilloscope. In one embodiment, a person can inspect the data directly at the electronic measuring device 204 by looking at a time-domain or frequency domain trace of the output signal or by analyzing appropriate waveform metrics (e.g., amplitude). Sample outputs in both the time-domain and frequency domain are shown below with reference to FIGS. 4 and 5. Alternatively, the stored data is sent to the local computer 202 and/or the remote computer 200 for analysis by either of the computers or a person who has access to the data on the computers.

In one embodiment, either the local computer 202 or the remote computer 200 run an algorithm that analyzes the data from the electronic measuring device 204 and determines if the measured total current is outside of a predetermined range. The predetermined range will change depending upon the power system and the type and size of surge arrestor. If the measured total current is outside of the predetermined range, in one embodiment, an alarm or message is created notifying the proper person that the surge arrestor should be replaced.

The monitoring system optionally also includes the voltage probe 208. The voltage probe 208 will register a voltage so long as the fuse 212 is not blown. The registered voltage will vary depending upon the voltage on the power line. However, if the fuse is blown the voltage probe 208 will register zero volts. When the voltage goes to zero, either a person monitoring the electronic measure device 204, a person monitoring the local computer 202 or the remote computer 200, or an algorithm running on the local computer 202 or the remote computer 200 determines that the fuse 212 has been blown. If the fuse 212 has been blown, there is a possibility that the surge arrestor is damaged and thus, the surge arrestor 214 should be identified as possibly damaged. A physical and electrical inspection of the surge arrestor 214 can then be made. In this manner, the current status of the surge arrestor 214 can be monitored without opening the cabinet in which the surge arrestor 214 is located.

Generally, when a surge arrestor fails, it will fail short and then typically blow open under a phase current. If the surge arrestor 214 remains shorted, fuse 212 will blow. If the surge arrestor 214 fails open, the circuit is unprotected and previously the only way to detect the failure was to inspect the surge arrestor. However, in the present embodiment, when the surge arrestor fails open the current probe 210 will no longer measure a total current and one of the computers, a person monitoring the data on one of the computers, or a person monitoring the electronic measuring device will detect the problem.

The control circuitry 216 controls the operation of the switching matrix 206 and thus controls the input to the electronic measuring device 204. In this manner, both the voltage probe 208 and the current probe 210 can be monitored using a single electronic measuring device 204.

The system shown in FIG. 2 allows for real time monitoring of a single surge arrestor. While real time monitoring may be beneficial in some embodiments, the system can be rather expensive. Thus, as described below with reference to FIG. 3, a more economical system that monitors a plurality of surge arrestors will be beneficial in some embodiments.

Referring now to FIG. 3, a block diagram is shown illustrating a monitoring system 350 for monitoring a plurality of surge arrestors in accordance with one embodiment. Shown is a remote computer 300, a local computer 302, an electronic measuring device 304, a first switching matrix 306, a second switching matrix 308, a plurality of voltage probes 310, a plurality of current probes 312, a plurality of fuses 314, a plurality of surge arrestors 316, control electronics 318, a first data line 320, a second data line 322, and a third data line 324.

The remote computer 300 is coupled to the local computer 302 which is coupled to the electronic measuring device 304. The local computer 302 is also coupled to the control electronics 318 that control the first switching matrix 306 and the second switching matrix 308. The first switching matrix 306 is coupled to the second switching matrix 308 through the first data line 320. The plurality of voltage probes 310 and the plurality of current probes 312 are coupled to the electronic measuring device 304 through the first switching matrix 306 and the second switching matrix 308.

In one embodiment, the second switching matrix 308, the plurality of voltage probes 310, the plurality of current probes 312, the plurality of fuses 314, and the plurality of surge arrestors 316 are located within a cabinet (such as the cabinet shown in FIG. 1). Additional cabinets can be connected to the first switching matrix 306 through the second data line 322 and the third data line 324. Advantageously, the more surge arrestors that are monitored using a single electronic measuring device, the more economical the entire system becomes. The first switching matrix and the second switching matrix are used to cycle through measurements from the plurality of current probes 312 and the plurality of voltage probes 310. Advantageously, this allows for a large number of surge arrestors to be monitored intermittently using a single electronic measuring device.

In one embodiment, the local computer 302 is connected to the electronic measuring device 304, for example, through a USB interface. As before, the electronic measurement device 304 can be integrated into the local computer 302. Data, corresponding to the signal being measured, is sent from the electronic measuring device 304 to the local computer 302. The local 302 computer is coupled to the control electronics 318 and thus is able to associate the data from the electronic measuring device 304 with a specific one of the plurality of surge arrestors 316. The local computer 302 can use the data to determine if the surge arrestor is operating within an acceptable predetermined range or a person looking at the data can determine if the surge arrestor is operating within an acceptable predetermined range. In one embodiment, a person can directly look at the electronic measuring device 304 and/or appropriate waveform metrics to determine if the surge arrestor is operating within the acceptable predetermined range.

In yet another embodiment, the data from the local computer 302 is sent to the remote computer 300 for analysis. In this embodiment, the remote computer 300 can also be connected to many different facilities and many different local computers 302. This allows multiple facilities each having one or more surge arrestors to all be monitor at one remote computer 300. Advantageously, this greatly reduces the need to have many employees visually inspecting surge arrestors at many different facilities. Additionally, as described above with reference to FIG. 1, this prevents the need to open the cabinets at the facility in order to determine a status of the surge arrestors.

In an alternative embodiment, the electronic measuring device 304 is capable of directly connecting to a network, for example, using an Ethernet connection. In this embodiment, the local computer 302 can be removed from the system and the electronic measuring device 304 can send data corresponding to the signal from the probes directly to the remote computer 300.

Referring to FIG. 4, a graphical representation is shown of a total current of a surge arrestor as measured by an oscilloscope in accordance with one embodiment. The total current 400 shown is for a healthy surge arrestor during normal operation. The total current 400 is at a frequency of 60 Hertz and has an amplitude of approximately 0.0030 Amps. It should be understood that the shown total current is dependent upon the specific line voltage and surge arrestor being monitored and thus, will vary from system to system.

If the total current decreases in amplitude, this indicates a reduction in the capacitance of the surge arrestor and indicates that the surge arrestor is starting to fail. If the current goes to zero Amps, the surge arrestor has failed and need to be changed. If the surge arrestor is being over voltaged or is starting to draw a base current, the current will start to increase. An increase in the current also indicates that the surge arrestor may fail. Thus, by monitoring the total current, a status of the surge arrestor can be determined.

Referring to FIG. 5, a graphical representation is shown of a total current of a surge arrestor as measured by a spectrum analyzer in accordance with one embodiment. The graphical representation shown is the Fast Fourier Transform (FFT) of the current shown in FIG. 4. As can be seen, a spike 500 is located at 60 Hertz that corresponds to the 60 Hertz signal from FIG. 4.

While the invention herein disclosed has been described by means of specific embodiments and applications thereof, other modifications, variations, and arrangements of the present invention may be made in accordance with the above teachings other than as specifically described to practice the invention within the spirit and scope defined by the following claims.

We claim:

1. A system for monitoring a surge arrestor comprising:
a current probe for measuring a total current of the surge arrestor;
an electronic measuring device coupled to the current probe, the electronic measuring device for measuring a signal from the current probe, the signal corresponding to the total current of the surge arrestor;
a fuse coupled to the surge arrestor; and
a voltage probe coupled between the fuse and the surge arrestor.

2. The system of claim 1 further comprising a first computer coupled to the electronic measuring device, the first computer for receiving data corresponding to the signal measured by the electronic monitoring device.

3. The system of claim 2 further comprising a second computer coupled to the first computer over a network.

4. The system of claim 2 wherein the first computer is coupled to the electronic measuring device over a network.

5. The system of claim 2 wherein the computer determines a status of the surge arrestor based upon the data received from the electronic measuring device.

6. The system of claim 1 wherein the electronic measuring device is a spectrum analyzer, an oscilloscope, a stand-alone instrument, or integrated into a computer.

7. The system of claim 1 further comprising a switch coupled to the voltage probe and the current probe.

8. The system of claim 7 wherein an output from the switch is coupled to the electronic measuring device.

9. A method for monitoring a surge arrestor comprising:
coupling a first current probe to a first surge arrestor;
coupling a voltage probe to the first surge arrestor;
measuring an output of the first current probe and the voltage probe at an electronic measuring device; and
determining a status of the first surge arrestor based upon the measured output of the current probe and the voltage probe.

10. The method of claim 9 further comprising sending data corresponding to the measured output of the first current probe to a computer; wherein the step of determining a status of the first surge arrestor is performed by the computer.

11. The method of claim 9 further comprising:
coupling a second current probe to a second surge arrestor;
measuring an output of the second current probe at the electronic measuring device; and
determining a status of the second surge arrestor based upon the measured output of the current probe.

12. The method of claim 11 further comprising:
sending data corresponding to the measured output of the first current probe to a computer, wherein the step of determining a status of the first surge arrestor is performed by the computer; and
sending data corresponding to the measured output of the second current probe to the computer, wherein the step of determining a status of the second surge arrestor is performed by the computer.

13. A monitoring system comprising:
a surge arrestor;
a fuse coupled to the surge arrestor;
a probe coupled between the fuse and the surge arrestor; and
an electronic measuring device coupled to the probe, the electronic measuring device for measuring a signal from the probe, the signal corresponding to a status of the surge arrestor.

14. The system of claim 13 further comprising a first computer coupled to the electronic measuring device, the first computer for receiving data corresponding to the signal measured by the electronic monitoring device.

15. The system of claim 14 further comprising a second computer coupled to the first computer over a network.

16. The system of claim 14 wherein the first computer is coupled to the electronic measuring device over a network.

17. The system of claim 13 wherein the computer determines a status of the surge arrestor based upon the data received from the electronic measuring device.

18. The system of claim 13 wherein the electronic measuring device is a spectrum analyzer, an oscilloscope, a stand-alone instrument, or integrated into a computer.

19. A monitoring system comprising:
a plurality of surge arrestors;
a plurality of fuses coupled to the surge arrestors;
a plurality of probes coupled, each one of the plurality of probes coupled to one of the plurality of surge arrestors, the plurality of probes comprising at least one current probe and one voltage probe;
a switching matrix coupled to the plurality of probes; and
an electronic measuring device coupled to the switch, the electronic measuring device for measuring signals from the first plurality of probes, the signals corresponding to a status of each of the plurality the surge arrestors.

20. The monitoring system of claim 19 further comprising a first computer coupled to the electronic measuring device, the first computer for receiving data corresponding to signals measured by the electronic monitoring device.

21. The monitoring system of claim 20 further comprising a second computer coupled to the first computer over a network.
